(19) United States
(12) Patent Application Publication
(10) Pub. No.: US 2023/0083256 A1
(43) Pub. Date: Mar. 16, 2023

(54) 3D Printed Diamond/Metal Matrix Composite Material and Preparation Method and Use thereof

(71) Applicant: CENTRAL SOUTH UNIVERSITY, Changsha (CN)

(72) Inventors: Qiuping WEI, Changsha (CN); Kechao ZHOU, Changsha (CN); Li MA, Changsha (CN); Kaitang HUANG, Changsha (CN); Jun LI, Changsha (CN)

(73) Assignee: CENTRAL SOUTH UNIVERSITY, Changsha (CN)

(21) Appl. No.: 17/945,099

(22) Filed: Sep. 15, 2022

(30) Foreign Application Priority Data
Sep. 15, 2021 (CN) 202111078536.1

(51) Int. Cl. B22F 10/38; B22F 10/28; B22F 3/105; B22F 10/366; B22F 3/10

(52) U.S. Cl. CPC B22F 10/38; B22F 3/105; B22F 3/1003; B22F 10/28; B22F 10/366; B33Y 10/00

(57) ABSTRACT

A 3D printed diamond/metal matrix composite material and a preparation method and application thereof are provided. The composite material includes core-shell doped diamond, a metal matrix, and an additive, where the core-shell doped diamond includes a core, a transition layer, a shell, a coating, a porous layer, and a modification layer. The preparation method includes: uniformly mixing the diamond, the metal matrix, and the additive and performing 3D printing according to a 3D CAD slice model to obtain the composite material designed by the model. The metal matrix and the diamond surface of the composite material are mainly metallurgically bound, which can improve the binding strength between the diamond and the metal matrix, thereby improving the use properties of the composite material and a diamond tool. The core-shell doped diamond has good ablation resistance, and can effectively avoid and reduce thermal damage to diamond in a 3D printing forming process.

### CROSS REFERENCE TO THE RELATED APPLICATIONS

This application is based upon and claims priority to Chinese Patent Application No. 202111078536.1, filed on Sep. 15, 2021, the entire contents of which are incorporated herein by reference.

### TECHNICAL FIELD

The present disclosure belongs to the field of composite materials, and in particular relates to a 3D printed diamond/metal matrix composite material and a preparation method and use thereof.

### BACKGROUND

With rapid development of science and technology, the power and integration of electronic equipment used in aerospace, military, industry, national production and other fields are getting higher and higher, while heat dissipation has become an important factor restricting the development of these industries. Especially, with the advent of the 5G communication era, the integration of electronic and semi-finished devices has increased geometrically, which has caused the heat density of electronic devices to increase rapidly. Studies have shown that the failure rate of electronic components approximately doubles for every 10° C. increase in temperature of the electronic components. In addition, 55% of failures in electronic equipment are caused by overheating of electronic devices and lack of reliable and comprehensive temperature control measures.

Diamond has an extremely high thermal conductivity of 2200 W/(mK), a relatively low thermal expansion coefficient (8.6×10⁻⁷/K⁻¹) and a relatively low density (3.52 g/cm³). Using diamond as a reinforcement for an electronic packaging material can make a composite material have relatively high thermal conductivity, and meet the requirements for a low expansion coefficient and light weight.

By combining diamond and a metal matrix material to give full play to excellent thermal conductivity and mechanical properties thereof, a diamond/metal matrix composite material with a relatively high thermal conductivity and a matching thermal expansion coefficient is prepared, which is also one of the most promising electronic packaging materials at present. Also, owning to high hardness, high wear resistance, and the like of diamond, a diamond/metal matrix composite material can also be used for forming diamond tools (such as grinding heads, grinding discs, and grinding knives).

A 3D printing technology uses laser as an energy source, and scans a metal powder bed layer by layer according to a path planned in a 3D CAD slice model. The scanned metal powder is melted and solidified to achieve a metallurgical bonding effect, and finally a metal part designed by the model is obtained. The technology overcomes the difficulties in traditional technologies for manufacturing metal parts of complex shapes, and can directly form metal parts with a nearly complete density and good mechanical properties.

However, when preparing the diamond/metal matrix composite material by the existing 3D printing technology, the prepared diamond/metal matrix composite material does not have high density, because a high laser power is required for preparing a high-density diamond/metal matrix composite material, and the laser beam generated will cause obvious damage to the diamond, some of which may be graphitized. If a low laser power is used, although thermal damage to the diamond is small, the prepared diamond/metal matrix composite material has a low density (70-80%) and insufficient properties.

### SUMMARY

In view of defects of the prior art, the objective of the present disclosure is to provide a 3D printed diamond/metal matrix composite material and a preparation method and use thereof. The present disclosure firstly performs multi-layer modification on diamond grits to effectively prevent thermal damage, and also improve the wettability with a metal matrix.

To achieve the foregoing objective, the present disclosure uses the following technical solutions.

The present disclosure provides a method for preparing the 3D printed diamond/metal matrix composite material, including the following steps: uniformly mixing core-shell doped diamond, metal powder and an additive to obtain a mixture, placing the mixture in laser selective melting equipment according to a 3D model of a product, performing 3D printing to obtain a printed body, and then performing atmospheric pressure heat treatment to obtain the diamond/metal matrix composite material, where the additive is a rare earth element, the core-shell doped diamond includes diamond grits and a diamond surface modified layer, and the diamond surface modified layer includes a diamond transition layer and a doped diamond shell layer from the inside to the outside.

In the preparation method of the present disclosure, the core-shell doped diamond is used as a reinforcement of which the surface is provided with the doped diamond shell layer having a good wettability with a metal material. The diamond transition layer is provided between the doped diamond shell layer and the diamond grits to maintain the original properties of single crystal diamond, such as high thermal conductivity, high hardness and high wear resistance. Adding a small amount of rare earth element can refine crystal grains of the matrix, purify the interface between the diamond and the matrix, promote the reaction between carbides in the matrix and the diamond, and further improve the bonding state between the metal matrix and the diamond, thereby improving the interface binding state between the matrix and the diamond. Finally, atmospheric pressure heat treatment is performed after forming to promote healing of microcracks, eliminate structural defects, and further improve the material properties.

In addition, since the diamond surface modified layer of the present disclosure can protect the diamond grits, the core-shell doped diamond has good ablation resistance, and can effectively avoid and reduce thermal damage to the diamond during a 3D printing forming process. Therefore, high laser power can be used for printing to obtain a high-density composite material. In addition, in the present disclosure, atmospheric pressure heat treatment is performed after 3D printing, which can effectively improve machinability, reduce residual stress, stabilize dimensions, reduce deformation and crack tendency, refine grains, adjust the structure, and eliminate structural defects. After the atmospheric pressure heat treatment, the properties of a composite material can be greatly improved when used as a wear-resistant material.

By the method of the present disclosure, 3D printed diamond/metal matrix composite materials of any structure may be prepared, for example, a functionally graded structure, an internal cooling channel, different lattice structures, or various structures designed according to actual requirements can be arranged in the 3D printed diamond/metal matrix composite material.

In a preferred solution, the core-shell doped diamond has a single crystal structure and a particle size of 5 -300 µm.

In the present disclosure, the diamond grits may be pure single crystal diamond prepared at high temperature and high pressure, or natural single crystal diamond.

In a preferred solution, the diamond transition layer has a polycrystalline structure and a thickness of 5 nm to 2 µm.

In a preferred solution, the doped diamond shell layer has a thickness of 5 nm to 100 µm, and is doped by one of or a combination of more of constant doping, multilayer variable doping and gradient doping, with a doping element selected from one or more of boron, nitrogen, phosphorus and lithium.

Further preferably, the doped diamond shell layer is doped by gradient doping, and the gradient doping is performed in such a manner that the concentration of a doping element increases from 0 ppm to 3000-30000 ppm from the inside to the outside.

In a preferred solution, a preparation process of the diamond reinforcement includes: first, depositing a diamond transition layer on the surfaces of diamond grits by chemical deposition, and then growing a doped diamond shell layer on the surface of the diamond transition layer by hot wire chemical vapor deposition.

Further preferably, a process of growing the doped diamond shell layer by hot wire chemical vapor deposition is performed in the presence of a fed gas of hydrogen, methane and a doping gas source in a mass flow ratio of 97:2:(0.1-0.7), at a growth pressure of 2-5 Kpa and a growth temperature of 800-850° C. 2-6 times. After each growth, carrier particles are taken out and shaken before continuing the growth, the growth lasts for 1-20 h each time, and the doping gas source is selected from at least one of ammonia, phosphine and borane.

Further preferably, when the doped diamond shell layer is doped by gradient doping, the gas flow is fed in three periods: in the first period, the mass flow ratio of CH₄ to H₂ to the doping gas source in the fed gas is 2:97:(0.1-0.25); in the second period, the mass flow ratio of CH₄ to H₂ to the doping gas source in the fed gas is 2:97:(0.3-0.45)sccm; and in the third period, the mass flow ratio of CH₄ to H₂ to the doping gas source in the fed gas is 2:97:(0.5-0.6).

In a preferred solution, the diamond surface modified layer further includes at least one of a coating, a porous layer and a modification layer, where the coating is a boron film deposited by chemical vapor deposition on the surface of the doped diamond shell layer, and the boron film deposited by chemical vapor deposition has a thickness of 10 nm to 200 µm; the porous layer refers to a porous structure prepared by etching the surface of the shell layer; and the modification layer is the outermost layer of the diamond surface modified layer, and includes one of or a combination of more of metal modification, carbon material modification, and organic matter modification.

In the practical operation process, the porous layer may be etched by one of or a combination of more of techniques of plasma etching, high-temperature oxidation etching, and nano metal nanoparticle etching.

In a preferred solution, the particle size of the metal powder is 10-50 µm.

In a preferred solution, the metal powder is selected from one of copper powder, aluminum powder, silver powder, nickel powder, cobalt powder, iron powder, titanium powder, vanadium powder, tin powder, magnesium powder, chromium powder and zinc powder, or is an alloy powder thereof.

In a preferred solution, the rare earth element is selected from at least one of lanthanum, cerium, neodymium, europium, gadolinium, dysprosium, holmium, ytterbium, lutetium, yttrium, and scandium.

In a preferred solution, the mass fraction of the core-shell doped diamond in the mixture is 5% to 60%.

In a preferred solution, the mass fraction of the additive in the mixture is 0.05% to 1%.

In the practical operation process, the core-shell doped diamond, the metal powder and the additive are uniformly mixed by ball milling to obtain the mixture.

In a preferred solution, the 3D printing is performed in an argon atmosphere at a power of 100-800 W, a scanning speed of 100-800 mm/s, a scanning distance of 0.04-0.2 mm, a temperature field of 673-1273 K, and a powder thickness of less than or equal to 0.6 mm, and the 3D printing is laser printing or electron beam printing.

Further preferably, the power is 400-800 W. In the present disclosure, a high laser power may be used to prepare a high-density composite material while ensuring that there is almost no thermal damage to the diamond.

In a preferred solution, the atmospheric pressure heat treatment is performed at a vacuum degree of 10-100 pa, a heating temperature of 200-800° C., a gas pressure of 2-15 Mpa, and a pressure holding time of 30-300 min.

In the present disclosure, the gas referred to in the gas pressure is any one of N₂ and Ar.

In a preferred solution, the prepared diamond/metal matrix composite material has a density of 70-98%, preferably 85-95%.

In a preferred solution, the volume fraction of the core-shell doped diamond in the prepared diamond/metal matrix composite material is not less than 5%.

The present disclosure further provides a diamond/metal matrix composite material prepared by the above preparation method.

The present disclosure further provides use of the diamond/metal matrix composite material prepared by the above preparation method as a packaging material or a wear-resistant material.

### Beneficial Effects

The present disclosure can realize alloying of a metal matrix, realize effective inlaying of diamond, obtain a metal matrix diamond composite material with ideal hardness and wear resistance, and manufacture parts with complex structures from the metal matrix diamond composite material. Adding a small amount of rare earth element in a binder can refine crystal grains of the matrix, purify the interface between the diamond and the matrix, promote the reaction between carbides in the matrix and the diamond, and further improve the bonding state between the metal matrix and the diamond, thereby improving the interface binding state between the matrix and the diamond. However, for different matrix materials, the rare earth elements to be added need to be selected. To improve the interface binding strength while ensuring thermal expansion adaptation, atmospheric pressure heat treatment is performed after forming to promote healing of microcracks, eliminate structural defects, and regulate properties.

The core-shell doped diamond designed by the present disclosure has good ablation resistance, and can effectively avoid and reduce thermal damage to diamond in a 3D printing forming process.

### DETAILED DESCRIPTION OF THE EMBODIMENTS

### Example 1

### Preparation of core-shell doped diamond

Using 150 µm single crystal diamond grits as a raw material, a polycrystalline diamond transition layer was deposited on the surfaces of the diamond grits by chemical deposition in the presence of a fed atmosphere of CH₄ and H₂ in a mass flow ratio of 2:98 twice for 20 min each time, and finally a polycrystalline diamond transition layer with a maximum thickness of 400 nm was obtained.

Then, a doped diamond shell layer was grown on the surface of the polycrystalline diamond transition layer by hot wire chemical vapor deposition to obtain a diamond reinforcement. The deposition was performed at a hot wire distance of 10 mm, a hot wire thickness of 0.5 mm, a growth temperature of 850° C., and a deposition pressure of 3 KPa, and a diamond film having a thickness of 2 µm was prepared by controlling the deposition time. The chemical vapor deposition was performed in the presence of a fed gas of CH₄, H₂ and B₂H₆ in a mass flow ratio of 2:97:1 at a growth pressure of 3 Kpa twice. After each growth, carrier particles were taken out and shaken before continuing the growth, and the growth lasted for 1 h each time.

The core-shell doped diamond was compounded with metal by 3D printing. The core-shell doped diamond, iron powder, nickel powder and lanthanum powder were mixed uniformly to obtain a mixture, where the mass ratio of the core-shell doped diamond to the sum of iron powder and nickel powder to the lanthanum powder was 30%:69.9%:0.1%.

The mixture was placed in laser selective melting equipment according to a 3D model of a product, and 3D printing was performed in an argon atmosphere at a laser power of 150 W, a scanning speed of 700 mm/s, a scanning distance of 0.06 mm, a temperature field of 773 K, and a powder thickness of 0.4 mm to obtain a 3D printed body. Then, the 3D printed body was subjected to atmospheric pressure heat treatment in a nitrogen atmosphere at a vacuum degree of lower than 100 pa, a heating temperature of 300° C., a gas pressure of 6 Mpa, and a pressure holding time of 1 h to obtain the diamond/metal matrix composite material.

The prepared diamond/metal matrix composite material in the present example had a density of 70%, and in the prepared diamond/metal matrix composite material, the volume fraction of the core-shell doped diamond was 30%.

The prepared composite material had a hardness of greater than or equal to 90 HRB, a service life of 1.5 times or more than that of an abrasive tool made of a superhard material prepared by the traditional technology, a wear ratio increased by 60% or more, and heat resistance of 800° C. or above.

### Example 2

### Preparation of core-shell doped diamond

Using 150 µm single crystal diamond grits as a raw material, a polycrystalline diamond transition layer was deposited on the surfaces of the diamond grits by chemical deposition in the presence of a fed atmosphere of CH₄ and H₂ in a mass flow ratio of 2:98 twice for 20 min each time, and finally a polycrystalline diamond transition layer with a maximum thickness of 400 nm was obtained.

Then, a doped diamond shell layer was grown on the surface of the polycrystalline diamond transition layer by hot wire chemical vapor deposition to obtain a diamond reinforcement. The deposition was performed at a hot wire distance of 10 mm, a hot wire thickness of 0.5 mm, a growth temperature of 850° C., and a deposition pressure of 3 KPa, and a diamond film having a thickness of 3 µm was prepared by controlling the deposition time. The chemical vapor deposition was performed in three periods for growth deposition, where in the first period of deposition, the mass flow ratio of CH₄ to H₂ to B₂H₆ in the fed gas was 2:97:0.15; in the second period of deposition, the mass flow ratio of CH₄ to H₂ to B₂H₆ in the fed gas was 2:97:0.35 sccm; and in the third period of deposition, the mass flow ratio of CH₄ to H₂ to B₂H₆ in the fed gas was 2:97:0.55. The growth pressure was 3 Kpa. After each growth, carrier particles were taken out and shaken before continuing the growth, and the growth lasted for 1 h each time.

The core-shell doped diamond was compounded with metal by 3D printing. The core-shell doped diamond, iron powder, nickel powder, cobalt powder and cerium powder were mixed uniformly to obtain a mixture, where the mass ratio of the core-shell doped diamond to the sum of iron powder, nickel powder and cobalt powder to the cerium powder was 35%:64.9%:0.1%.

The mixture was placed in laser selective melting equipment according to a 3D model of a product, and 3D printing was performed in an argon atmosphere at a laser power of 450 W, a scanning speed of 300 mm/s, a scanning distance of 0.05 mm, a temperature field of 773 K, and a powder thickness of 0.4 mm to obtain a 3D printed body. Then, the 3D printed body was subjected to atmospheric pressure heat treatment in a nitrogen atmosphere at a vacuum degree of lower than 100 pa, a heating temperature of 200° C., a gas pressure of 6 Mpa, and a pressure holding time of 1 h to obtain the diamond/metal matrix composite material.

The prepared diamond/metal matrix composite material in the present example had a density of 90%, and in the prepared diamond/metal matrix composite material, the volume fraction of the core-shell doped diamond was 35%.

The diamond/metal matrix composite material tested had a hardness of greater than or equal to 120 HRB, a service life of 2 times or more than that of an abrasive tool made of a superhard material prepared by the traditional technologies (e.g. electroplating, hot pressing sintering, non-pressure infiltration and high-temperature brazing), a wear ratio increased by 80% above, and heat resistance of 800° C. or above.

### Example 3

### Preparation of core-shell doped diamond

Using 200 µm single crystal diamond grits as a raw material, a polycrystalline diamond transition layer was deposited on the surfaces of the diamond grits by chemical deposition in the presence of a fed atmosphere of CH₄ and H₂ in a mass flow ratio of 2:98 twice for 20 min each time, and finally a polycrystalline diamond transition layer with a maximum thickness of 400 nm was obtained.

Then, a doped diamond shell layer was grown on the surface of the polycrystalline diamond transition layer by hot wire chemical vapor deposition to obtain a diamond reinforcement. The deposition was performed at a hot wire distance of 10 mm, a hot wire thickness of 0.5 mm, a growth temperature of 850° C., and a deposition pressure of 3 KPa, and a diamond film having a thickness of 2 µm was prepared by controlling the deposition time. The chemical vapor deposition was performed in the presence of a fed gas of CH₄, H₂ and B₂H₆ in a mass flow ratio of 2:97:1 at a growth pressure of 3 Kpa twice. After each growth, carrier particles were taken out and shaken before continuing the growth, and the growth lasted for 1 h each time.

A boron film was deposited by chemical vapor deposition on the surface of the doped diamond shell layer at a hot wire distance of 50 mm, a temperature of 800° C., and a deposition pressure of 3 KPa, and a diamond film having a thickness of 50 µm was prepared by controlling the deposition time. The chemical vapor deposition was performed in the presence of a fed gas of H₂ and B₂H₆ in a mass flow ratio of 95:5 twice. After each deposition, carrier particles were taken out and shaken before continuing the growth, and the growth lasted for 10 h each time.

### Compounding of the core-shell doped diamond with metal by 3D printing

The core-shell doped diamond, Cu—B alloy powder and lanthanum powder were mixed uniformly to obtain a mixture, and the mass ratio of the core-shell doped diamond to the Cu-B alloy powder to the lanthanum powder was 50%:49.9%:0.1%.

The mixture was placed in laser selective melting equipment according to a 3D model of a product, and 3D printing was performed in an argon atmosphere at a laser power of 400 W, a scanning speed of 300 mm/s, a scanning distance of 0.045 mm, a temperature field of 1073 K, and a powder thickness of 0.5 mm to obtain a 3D printed body. Then, the 3D printed body was subjected to atmospheric pressure heat treatment in an argon atmosphere at a vacuum degree of lower than 100 pa, a heating temperature of 400° C., a gas pressure of 8 Mpa, and a pressure holding time of 1 h to obtain the diamond/metal matrix composite material.

The prepared diamond/metal matrix composite material in the present example had a density of 85%, and in the prepared diamond/metal matrix composite material, the volume fraction of the core-shell doped diamond was 50%.

The diamond/metal matrix composite material tested had a thermal conductivity of 830 W/mK, a thermal expansion coefficient of 5×10⁻⁶/K, a density of less than 6 g/cm³, a bending resistance of 450 Mpa, and a surface roughness of less than 3.2 µm, and could be used at a temperature ranging from -50 to 500° C.

### Example 4

### Preparation of a diamond reinforcement

Using 200 µm single crystal diamond grits as a raw material, a polycrystalline diamond transition layer was deposited on the surfaces of the diamond grits by chemical deposition in the presence of a fed atmosphere of CH₄ and H₂ in a mass flow ratio of 2:98 twice for 20 min each time, and finally a polycrystalline diamond transition layer with a maximum thickness of 400 nm was obtained.

Then, a doped diamond shell layer was grown on the surface of the polycrystalline diamond transition layer by hot wire chemical vapor deposition to obtain a diamond reinforcement. The deposition was performed at a hot wire distance of 10 mm, a hot wire thickness of 0.5 mm, a growth temperature of 850° C., and a deposition pressure of 3 KPa, and a diamond film having a thickness of 3 µm was prepared by controlling the deposition time. The chemical vapor deposition was performed in three periods for growth deposition, where in the first period of deposition, the mass flow ratio of CH₄ to H₂ to B₂H₆ in the fed gas was 2:97:0.15; in the second period of deposition, the mass flow ratio of CH₄ to H₂ to B₂H₆ in the fed gas was 2:97:0.35 sccm; and in the third period of deposition, the mass flow ratio of CH₄ to H₂ to B₂H₆ in the fed gas was 2:97:0.55. The growth pressure was 3 Kpa. After each growth, carrier particles were taken out and shaken before continuing the growth, and the growth lasted for 1 h each time.

Then, the doped diamond shell layer was etched into a porous structure by plasma in a tube furnace with a plasma device at a temperature of 800° C. and a vacuum degree of n 0 pa or below in a hydrogen or oxygen atmosphere with a gas flow rate of 35 sccm for 60 min to obtain a porous modified layer.

Then, metal modification was performed by the physical vapor deposition technology in a high-purity argon atmosphere with a flow rate of 30 sccm, at a vacuum degree of 0.5-1 Pa, a temperature of 473 KK and a power of 200 W for a sputtering time of 30 min to obtain a thickness of 3 µm.

### Compounding of the core-shell doped diamond with metal by 3D printing

The core-shell doped diamond, Cu—Zr alloy powder and lanthanum powder were mixed uniformly to obtain a mixture, and the mass ratio of the core-shell doped diamond to the Cu-Zr alloy powder to the lanthanum powder was 50%:49.9%:0.1%.

The mixture was placed in laser selective melting equipment according to a 3D model of a product, and 3D printing was performed in an argon atmosphere at a laser power of 400 W, a scanning speed of 400 mm/s, a scanning distance of 0.045 mm, a temperature field of 1073 K, and a powder thickness of 0.5 mm to obtain a 3D printed body. Then, the 3D printed body was subjected to atmospheric pressure heat treatment in an argon atmosphere at a vacuum degree of lower than 100 pa, a heating temperature of 300° C., a gas pressure of 10 Mpa, and a pressure holding time of 2 h to obtain the diamond/metal matrix composite material.

The prepared diamond/metal matrix composite material in the present example had a density of 95%, and in the prepared diamond/metal matrix composite material, the volume fraction of the core-shell doped diamond was 50%.

The diamond/metal matrix composite material tested had a thermal conductivity of 900 W/mK, a thermal expansion coefficient of 4.8×10⁻⁶/K,

a density of less than 6 g/cm³, a bending resistance of 580 Mpa, and a surface roughness of less than or equal to 3.2 µm, and could be used at a temperature ranging from -50 to 500° C.

### Comparative example 1

Other conditions were the same as in Example 1, except that no rare earth elements were added. The interface of the composite material prepared was easily debonded and cracked under the interaction of heating and cooling, and the binding performance was insufficient, resulting in lots of defects at the interface, and resulting in a decline in the overall properties of the material and low thermal conductivity during use.

### Comparative example 2

Other conditions were the same as in Example 1, except that no diamond transition layer was formed in the core-shell doped diamond. The diamond/metal matrix composite material without the transition layer had weak binding strength, low wettability, easy oxidation on the surface, easy carbonization at high temperature, and low ablation resistance.

### Comparative example 3

Other conditions were the same as in Example 1, except that atmosphere pressure heating treatment was not performed after 3D printing. The obtained material has internal stress, deformation and cracks, and a microstructure which is not delicate.

What is claimed is:

1. A method for preparing a 3D printed diamond/metal matrix composite material, comprising the following steps:
uniformly mixing a core-shell doped diamond, a metal powder, and an additive to obtain a mixture,
placing the mixture in a laser selective melting equipment according to a 3D model of a product,
performing a 3D printing to obtain a printed body, and
performing an atmospheric pressure heat treatment on the printed body to obtain the 3D printed diamond/metal matrix composite material,
wherein the additive is a rare earth element, the core-shell doped diamond is composed of diamond grits and a diamond surface modified layer, and the diamond surface modified layer comprises a diamond transition layer and a doped diamond shell layer from an inside to an outside.

2. The method for preparing the 3D printed diamond/metal matrix composite material according to claim 1, wherein the core-shell doped diamond has a single crystal structure and a particle size of 5 µm-300 µm, the diamond transition layer has a polycrystalline structure and a thickness of 5 nm to 2 µm,
the doped diamond shell layer has a thickness of 5 nm to 100 µm and is doped by at least one of a constant doping, a multilayer variable doping, and a gradient doping, with a doping element selected from at least one of boron, nitrogen, phosphorus, and lithium.

3. The method for preparing the 3D printed diamond/metal matrix composite material according to claim 1,
wherein the diamond surface modified layer further comprises at least one of a coating, a porous layer, and a modification layer,
wherein the coating is a boron film deposited by a chemical vapor deposition on a surface of the doped diamond shell layer, and the boron film deposited by the chemical vapor deposition has a thickness of 10 nm to 200 µm; the porous layer refers to a porous structure prepared by etching the surface of the doped diamond shell layer; and the modification layer is an outermost layer of the diamond surface modified layer, and the modification layer comprises at least one of a metal modification, a carbon material modification, and an organic matter modification.

4. The method for preparing the 3D printed diamond/metal matrix composite material according to claim 1, wherein the metal powder has a particle size of 10 µm-50 µm and is selected from one of a copper powder, an aluminum powder, a silver powder, a nickel powder, a cobalt powder, an iron powder, a titanium powder, a vanadium powder, a tin powder, a magnesium powder, a chromium powder, a zinc powder, an alloy powder of copper, an alloy powder of aluminum, an alloy powder of silver, an alloy powder of nickel, an alloy powder of cobalt, an alloy powder of iron, an alloy powder of titanium, an alloy powder of vanadium, an alloy powder of tin, an alloy powder of magnesium, an alloy powder of chromium, and an alloy powder of zinc; and
the rare earth element is selected from at least one of lanthanum, cerium, neodymium, europium, gadolinium, dysprosium, holmium, ytterbium, lutetium, yttrium, and scandium.

5. The method for preparing the 3D printed diamond/metal matrix composite material according to claim 1, wherein a mass fraction of the core-shell doped diamond in the mixture is 5%-60%, and a mass fraction of the additive in the mixture is 0.05%-1%.

6. The method for preparing the 3D printed diamond/metal matrix composite material according to claim 1, wherein the 3D printing is performed in an argon atmosphere at a power of 100 W-800 W, a scanning speed of 100 mm/s-800 mm/s, a scanning distance of 0.04 mm-0.2 mm, and a temperature field of 673 K-1273 K, and the metal powder has a thickness of less than or equal to 0.6 mm, and the 3D printing is a laser printing or an electron beam printing.

7. The method for preparing the 3D printed diamond/metal matrix composite material according to claim 1, wherein the atmospheric pressure heat treatment is performed at a vacuum degree of 10 pa-100 pa, a heating temperature of 200° C.-800° C., a gas pressure of 2 Mpa-15 Mpa, and a pressure holding time of 30 min-300 min.

8. The method for preparing the 3D printed diamond/metal matrix composite material according to claim 1,
wherein the 3D printed diamond/metal matrix composite material has a density of 70%-98%, and
wherein in the 3D printed diamond/metal matrix composite material, a volume fraction of the core-shell doped diamond is not less than 5%.

9. A 3D printed diamond/metal matrix composite material prepared by the method according to claim 1.

10. A method of use of the 3D printed diamond/metal matrix composite material prepared by the method according to claim 1 as a packaging material or a wear-resistant material.

11. The 3D printed diamond/metal matrix composite material according to claim 9,
wherein in a process of preparing the 3D printed diamond/metal matrix composite material, the core-shell doped diamond has a single crystal structure and a particle size of 5 µm-300 µm, the diamond transition layer has a polycrystalline structure and a thickness of 5 nm to 2 µm,
the doped diamond shell layer has a thickness of 5 nm to 100 µm and is doped by at least one of a constant doping, a multilayer variable doping, and a gradient doping, with a doping element selected from at least one of boron, nitrogen, phosphorus, and lithium.

12. The 3D printed diamond/metal matrix composite material according to claim 9,
wherein in a process of preparing the 3D printed diamond/metal matrix composite material, the diamond surface modified layer further comprises at least one of a coating, a porous layer, and a modification layer,
wherein the coating is a boron film deposited by a chemical vapor deposition on a surface of the doped diamond shell layer, and the boron film deposited by the chemical vapor deposition has a thickness of 10 nm to 200 um; the porous layer refers to a porous structure prepared by etching the surface of the doped diamond shell layer; and the modification layer is an outermost layer of the diamond surface modified layer, and the modification layer comprises at least one of a metal modification, a carbon material modification, and an organic matter modification.

13. The 3D printed diamond/metal matrix composite material according to claim 9,
wherein in a process of preparing the 3D printed diamond/metal matrix composite material, the metal powder has a particle size of 10 µm-50 µm and is selected from one of a copper powder, an aluminum powder, a silver powder, a nickel powder, a cobalt powder, an iron powder, a titanium powder, a vanadium powder, a tin powder, a magnesium powder, a chromium powder, a zinc powder, an alloy powder of copper, an alloy powder of aluminum, an alloy powder of silver, an alloy powder of nickel, an alloy powder of cobalt, an alloy powder of iron, an alloy powder of titanium, an alloy powder of vanadium, an alloy powder of tin, an alloy powder of magnesium, an alloy powder of chromium, and an alloy powder of zinc; and
the rare earth element is selected from at least one of lanthanum, cerium, neodymium, europium, gadolinium, dysprosium, holmium, ytterbium, lutetium, yttrium, and scandium.

14. The 3D printed diamond/metal matrix composite material according to claim 9,
wherein in a process of preparing the 3D printed diamond/metal matrix composite material, a mass fraction of the core-shell doped diamond in the mixture is 5%-60%, and a mass fraction of the additive in the mixture is 0.05%-1%.

15. The 3D printed diamond/metal matrix composite material according to claim 9,
wherein in a process of preparing the 3D printed diamond/metal matrix composite material, the 3D printing is performed in an argon atmosphere at a power of 100 W-800 W, a scanning speed of 100 mm/s-800 mm/s, a scanning distance of 0.04 mm-0.2 mm, and a temperature field of 673 K-1273 K, and the metal powder has a thickness of less than or equal to 0.6 mm, and the 3D printing is a laser printing or an electron beam printing.

16. The 3D printed diamond/metal matrix composite material according to claim 9,
wherein in a process of preparing the 3D printed diamond/metal matrix composite material, the atmospheric pressure heat treatment is performed at a vacuum degree of 10 pa-100 pa, a heating temperature of 200° C.-800° C., a gas pressure of 2 Mpa-15 Mpa, and a pressure holding time of 30 min-300 min.

17. The 3D printed diamond/metal matrix composite material according to claim 9,
wherein the 3D printed diamond/metal matrix composite material has a density of 70%-98%, and
wherein in the 3D printed diamond/metal matrix composite material, a volume fraction of the core-shell doped diamond is not less than 5%.

18. The method of use of the 3D printed diamond/metal matrix composite material according to claim 10,
wherein in a process of preparing the 3D printed diamond/metal matrix composite material, the core-shell doped diamond has a single crystal structure and a particle size of 5 µm-300 µm, the diamond transition layer has a polycrystalline structure and a thickness of 5 nm to 2 µm,
the doped diamond shell layer has a thickness of 5 nm to 100 µm and is doped by at least one of a constant doping, a multilayer variable doping, and a gradient doping, with a doping element selected from at least one of boron, nitrogen, phosphorus, and lithium.

19. The method of use of the 3D printed diamond/metal matrix composite material according to claim 10,
wherein in a process of preparing the 3D printed diamond/metal matrix composite material, the diamond surface modified layer further comprises at least one of a coating, a porous layer, and a modification layer,
wherein the coating is a boron film deposited by a chemical vapor deposition on a surface of the doped diamond shell layer, and the boron film deposited by the chemical vapor deposition has a thickness of 10 nm to 200 µm; the porous layer refers to a porous structure prepared by etching the surface of the doped diamond shell layer; and the modification layer is an outermost layer of the diamond surface modified layer, and the modification layer comprises at least one of a metal modification, a carbon material modification, and an organic matter modification.

20. The method of use of the 3D printed diamond/metal matrix composite material according to claim 10,
wherein in a process of preparing the 3D printed diamond/metal matrix composite material, the metal powder has a particle size of 10 µm-50 µm and is selected from one of a copper powder, an aluminum powder, a silver powder, a nickel powder, a cobalt powder, an iron powder, a titanium powder, a vanadium powder, a tin powder, a magnesium powder, a chromium powder, a zinc powder, an alloy powder of copper, an alloy powder of aluminum, an alloy powder of silver, an alloy powder of nickel, an alloy powder of cobalt, an alloy powder of iron, an alloy powder of titanium, an alloy powder of vanadium, an alloy powder of tin, an alloy powder of magnesium, an alloy powder of chromium, and an alloy powder of zinc; and
the rare earth element is selected from at least one of lanthanum, cerium, neodymium, europium, gadolinium, dysprosium, holmium, ytterbium, lutetium, yttrium, and scandium.
